(19) United States
(12) Patent Application Publication
(10) Pub. No.: US 2010/0101623 A1
(43) Pub. Date: Apr. 29, 2010

(54) PACKAGING STRUCTURE

(75) Inventors: Tzu-Chien WEI, Hsinchu City (TW); Chao PENG, Taipei County (TW); Jo-Lin LAN, Kaohsiung City (TW); Ya-Huei CHANG, Taoyuan County (TW); Wen-Chi HSU, Tainan County (TW); Hai-Peng CHENG, Taipei County (TW); Shien-Ping FENG, Hsinchu County (TW); Wen-Hsiang CHEN, Hsinchu City (TW)

Correspondence Address: BRIAN M. MCINNIS, 12th Floor, Ruttonjee House, 11 Duddell Street, Hong Kong, HK

(73) Assignee: TRIPOD TECHNOLOGY CORPORATION, TaoYuan County (TW)

(21) Appl. No.: 12/401,610

(22) Filed: Mar. 10, 2009

(30) Foreign Application Priority Data
Oct. 27, 2008 (TW) 97141197

(51) Int. Cl. H01L 31/042

(52) U.S. Cl. 136/244

(57) ABSTRACT

A packaging structure with a box for containing at least a portable electronic device is provided. The box has plates, which are connected to one another and surrounded to form an opening for the portable electronic device passing through, and a lid selectively covering or exposing the opening. First solar cells each fastened on an inner surface of each plate in the box. At least a cable electrically connects the first solar cells and is operated for electrically connecting the portable electronic device.

### RELATED APPLICATIONS

This application claims priority to Taiwan Application Serial Number 97141197, filed Oct. 27, 2008, which is herein incorporated by reference.

### BACKGROUND

1. Field of Invention

The present invention relates to a packaging structure for electronic devices. More particularly, the present invention relates to a charger for electronic devices.

2. Description of Related Art

Electronic devices usually are well packaged before being sold. The packaging structure may protect the electronic device from heat, water or pressure and may have beautiful patterns printed on the outside for better selling.

The packaging structure sometimes is a box, in which the electronic device, a user's manual, and peripheral equipment like a charger, cables, earphones, and/or USB connectors are contained. To protect the electronic device, the packaging structure may be made from card broad, wood, styrofoam, plastic, and/or acrylic resin. The surface of the packaging structure may be printed on or enclosed with advertisements to draw the consumer attention.

However, after buying an electronic device, consumers usually throw the packaging structures away, which may waste natural resources.

Therefore, a new packaging structure with multiple functions is needed. The new packaging structure may combine the function of original packaging structure, such as protecting electronic devices contained therein and/or advertising etc., and the function of charging the electronic devices.

### SUMMARY

A packaging structure is provided. The packaging structure comprises a box for containing at least a portable electronic device. The box comprises a plurality of plates and a lid. The plates are connected to each and surrounded to form a space for the portable electronic device and an opening. The lid may selectively cover or expose the opening. When the lid exposes the opening, the portable electronic device may pass through the opening to be placed in the box.

A plurality of solar cells are disposed in the box. Each solar cell is fastened on an inner surface of each plate in the box. A cable is electrically connected to the solar cells. The cable may electrically connect the portable electronic device.

When the box is placed in any environment with sufficient light, either in sunlight or under indoor lighting, the solar cells transform light into electric energy. The electric energy generated from the first solar cells may transfer to the portable electronic device via the cable to charge the portable electronic device.

The invention further provides another packaging structure. The packaging structure comprises at least a plate, which may be selectively folded to form a box or unfolded to be spread over a plane surface. When the plate is folded, at least a portable electronic device may be contained in the box.

A plurality of solar cells are fastened on the plate. When the plate is folded, the solar cells may be located in the box. Therefore, the box may protect the solar cells from heat, water, and external forces. In addition, the plate may be unfolded to expose the solar cells to light.

At least a cable is physically and electrically connected to the solar cells. The cable comprises a connector for connecting the portable electronic device. Therefore, the electric energy generated from the solar cells may transfer to the portable electronic device via the cable.

In the foregoing, the packaging structure has the box to protect the portable electronic device and the solar cells to generate electric energy for charging the portable electronic device.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

FIG. 1A is a three-dimensional view of a packaging structure according to an embodiment of this invention;

FIG. 1B is an exploded view of the packaging structure shown in FIG. 1A;

FIG. 1C is a three-dimensional view of the packaging structure shown in FIG. 1A;

FIG. 2A is a three-dimensional view of a packaging structure according to another embodiment of this invention;

FIG. 2B is an exploded view of the packaging structure shown in FIG. 2A;

FIG. 2C is a three-dimensional view of the packaging structure shown in FIG. 2A;

FIG. 3 is a three-dimensional view of a packaging structure according to another embodiment of this invention;

FIG. 4 is a three-dimensional view of a packaging structure according to another embodiment of this invention;

FIG. 5A is a top view of a packaging structure according to another embodiment according to this invention;

FIG. 5B is a cross-sectional view of the packaging structure shown in FIG. 5A;

FIG. 5C is a three-dimensional view of the packaging structure shown in FIG. 5A;

FIG. 6A is a top view of a packaging structure according to another embodiment according to this invention;

FIG. 6B is a cross-sectional view of the packaging structure shown in FIG. 6A;

FIG. 6C is a three-dimensional view of the packaging structure shown in FIG. 6A;

FIG. 7A is a top view of a packaging structure according to another embodiment according to this invention;

FIG. 7B is a cross-sectional view of the packaging structure shown in FIG. 7A; and

FIG. 7C is a three-dimensional view of the packaging structure shown in FIG. 7A.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

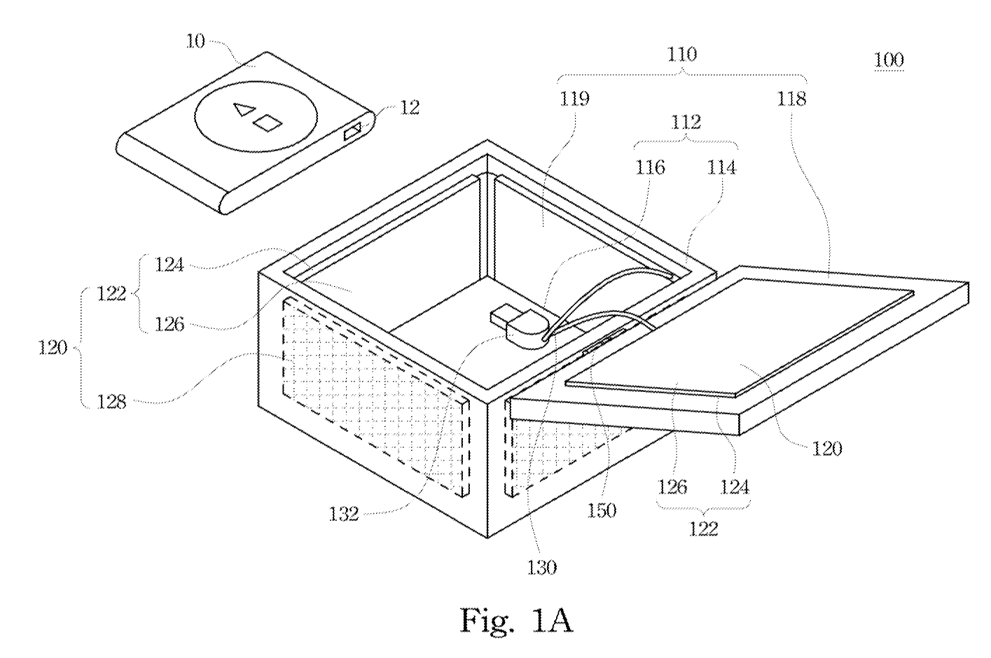

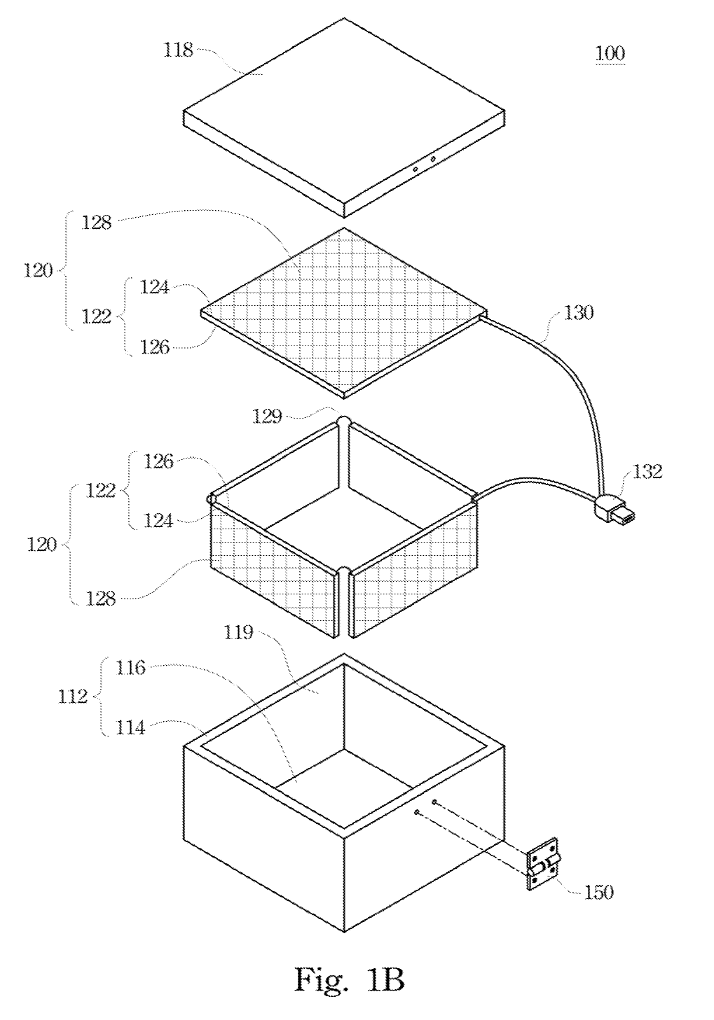

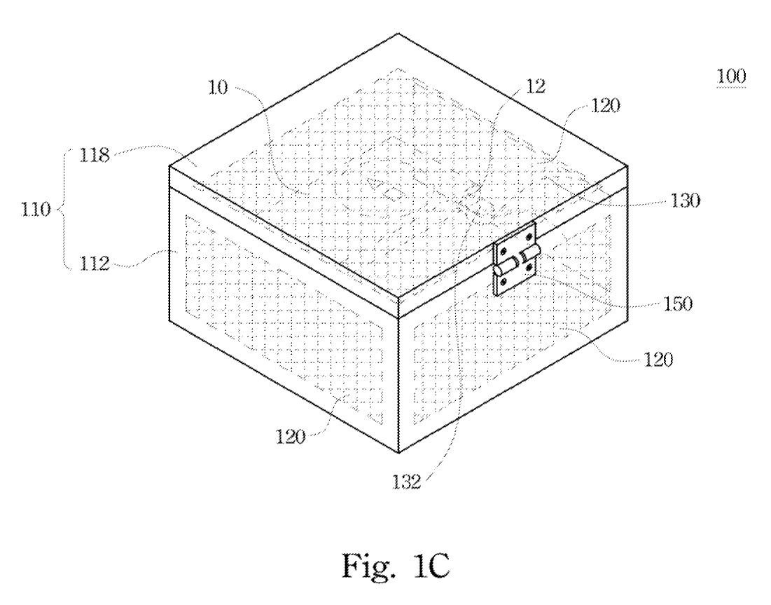

Please refer to FIG. 1A. FIG. 1A is a three-dimensional view of a packaging structure 100 according to an embodiment of this invention. The packaging structure 100 contains and charges a portable electronic device 10. The packaging structure 100 comprises a box 110 and many solar cells 120.

The box 110 of the packaging structure 100 may contain the portable electronic device 10 therein, and may be enclosed with printed paper or film as advertisements.

The box 110 comprises plates 112 and a lid 118. The plates 112 may be divided into side plates 114 and a bottom plate 116, wherein the side plates 114 are connected to each and the bottom plate 116. Specifically, the side plates surrounds and connects all edges of the bottom plate 116 to form a space like a pot. The side plates 114 are surrounded and connected to each to form an opening 119 of the space.

The lid 118 may selectively cover or expose the opening 119. In particular, the lid 118 may be placed over the opening 119 and the edge of the lid 118 may connect to the side plates 114 surrounding the opening 119 to cover the opening 119. On the other hand, the lid 118 may be taken off to expose the opening 119 and the space.

When storing the portable electronic device 10, the lid 118 may be taken off, and then the portable electronic device 10 may pass through the opening 119 to be contained in the box 110.

The lid 118 may physically connect or disconnect the plates 112. In some embodiments of this invention, the lid 118 and the plates 112 may be separated objects. The lid 118 is placed over the plates 112 only when it covers the opening 119. In other embodiments, the lid 118 connects the plates 112. For example, the lid 118 can connect the plates 112 via a pivot, a latch and/or fastening elements. Please notice that boxes 110 described hereafter are examples and are not used to limit the relation between the plates 112 and the lid 118.

Although the box 110 described hereafter is like a cube, the shape of the box 110 is not limited. In fact, the shape of the box 110 may be changed based on the size and the shape of the portable electronic device 10, product design, and etc. For example, the box 110 may be a cube, a cuboid, a cylinder, a cone, etc. Additionally, the shape of the lid 118 and the plates 112 may be changed.

The box 110 may be used to protect objects contained therein, wherein the object may be the portable electronic device 10, peripheral equipments like cables, earphones, batteries, USB connectors and/or etc. To protect the objects, the box 110 may be made of materials not easily broken or flexible. The box 110 may be made from papers like cardboards, corrugated papers and etc., or plastic materials like polycarbonate, acrylic resin, polystyrene and etc., or clothes, or leather.

Many solar cells 120 are fastened in the box 110. Each solar cell 120 is fastened on an inner surface of the plate 112 or an inner surface of the lid 118 so that it may be located inside the box 110. Therefore, the box 110 may protect the solar cells 120 from heat, water, and force. In one embodiment of this invention, the solar cells 120 are fastened only on the plates 112. In another embodiment of this invention, the solar cells 120 are fastened on the plates 112 and the lid 118. The arrangement of the solar cells 120 will be described below.

The solar cell 120 comprises a substrate 122, wherein the substrate 122 may be made from glass or other materials. The substrate 122 has a pair of opposite surfaces, which may be referred to as the first surface 124 and the second surface 126.

An active region 128 of the solar cell 120 is disposed on the first surface 124 of the substrate 122. When light is incident on the solar cell 120, the active region 128 may convert the light energy to electric energy. In general, the active region 128 may comprise photovoltaic cells such as PN junctions disposed thereon. The kinds and the materials of the solar cells 120 are not limited.

At least a cable 130 is electrically connected to the solar cells 120 and is operated for electrically connecting the portable electronic device 10. For example, the solar cells 120 may be a series connected via a wire 129, and the cable 130 may connect one of the solar cells 120. Additionally, the cable 130 may physically and electrically connect each of the solar cells 120.

The cable 130 comprises a connector 132 disposed on an end thereof to physically and electrically connect the portable electronic device 10. The forms of the connector 132 are many, such as a Universal Serial Bus (USB). In the embodiment of this invention, the connector 132 is a USB.

Therefore, when the solar cells 120 are placed in any environment with sufficient light, either under the sunlight or under the indoor lighting, the solar cells 120 may convert light to electric energy. The electric energy generated from the solar cells 120 may transfer to the portable electronic device 10 via the cable 130 to charge the portable electronic device 10.

Additionally, since the box 110 may contain the portable electronic device 10 therein, the volume and the surface area of the box 110 should be larger than the volume and the surface area of the portable electronic device 10. Contrary to conventional technology to install solar cells on a limited surface of the electronic device, the packaging structure 100 of the embodiment of this invention may have larger solar cells 120 fastened thereon.

It is to be understood that the following embodiments are by examples.

Please refer to FIG. 1A, FIG. 1B, and FIG. 1C at the same time. Both FIG. 1A and FIG. 1C are three-dimensional views of the packaging structure 100 according to the embodiment of this invention, wherein FIG. 1A shows the embodiment with the lid 118 opened and FIG. 1C shows the embodiment with the lid 118 closed. FIG. 1B is an exploded view of the packaging structure 100.

The side plates 114 of the box 110 may be transparent to allow light incident on the solar cells 120 inside the box 110, wherein the solar cells 120 may absorb the light energy and may convert the light energy to electric energy. In the embodiment of this invention, the plates 112, which comprise the side plates 114 and the bottom plate 116, are transparent.

The plates 112 are made from a material that is transparent and hard to be broken like a transparent plastic material, for example polycarbonate, acrylic resin, or polystyrene. In the embodiment of this invention, the plates 120 are made of the transparent acrylic resin.

As to the lid 118, the form, the kinds and the materials of the lid 118 are not limited. The lid 118 may be transparent or opaque. In the embodiment of this invention, the lid 118 is made from a material that is transparent and hard to be broken like a transparent plastic material, for example polycarbonate, acrylic resin, or polystyrene. Furthermore, in the embodiment of this invention, the lid 118 is made from the transparent acrylic resin the same as the plates 120.

In the embodiment of this invention, the lid 118 may connect the plates 112. In particular, the packaging structure 100 has a joining element 150 connected the lid 118 and the plates 112. The lid 118 may rotate around the plates 112 via the joining element 150 to selectively cover or expose the opening 119 of the box 110.

Each solar cell 120 is fastened on the inner surface of one of the plates 112. Specifically, the substrate 122 of the solar cell 120 is fastened on the inner surface of the side plate 114, which is the surface inside the box 110.

In the embodiment of this invention, the first surface 124 of the substrate 122 faces the inner surface of the side plate 114 so that the active region 128 faces the side plate 114. As the above, since the side plate 114 is transparent, light passes through the side plate 114 and is incident on the active region 128 of the solar cell 128 fastened to the side plate 114.

Additionally, some of the solar cells 120 may be fastened on the inner surface of the lid 118. Therefore, when the lid 118 covers the opening 119 of the box 110, the solar cells 120 fastened thereon may be contained inside the box 110.

The first surface 124 of the substrate 122 of the solar cell 120 fastened on the lid 118 is facing the inner surface of the lid 118 so that the active region 128 thereof faces the lid 118. In the foregoing, since the lid 118 of this embodiment is transparent, light passes through the lid 118 and is incident on the active region 128 of the solar cell 128 fastened to the lid 118.

As the above, the surface area of the box 110 is larger than the surface area of the portable electronic device 10. In the embodiment of this invention, the sum of superficial areas of the solar cells 120 fastened on the box 110 is larger than the superficial area of the portable electronic device 10. In particular, the sum of superficial areas of the active regions 128 of the solar cells 120 is larger than a superficial area of the portable electronic device 10.

When charging the portable electronic device 10 with the packaging structure 100 of the embodiment of this invention, the connector 132 may connect a port 12 of the portable electronic device 10. The portable electronic device 10 may be contained in the box 110 (or be located outside the box 110) with the lid 118 covering the opening 119. The box 110 may be placed in an environment with sufficient light, either in sunlight or in indoor lighting.

Because the plates 112 and the lid 118 of the box 110 are transparent, light can be incident on the solar cells 120, wherein the active regions 128 of the solar cells 120 absorbs the light and convert the light energy to electric energy. The electric energy may be transferred to the portable electronic device 10 via the cable 130 to charge the portable electronic device 10.

Please note that the packaging structure 100 of the embodiment of this invention does not comprise any batteries. The cable 130 is directly connected to the solar cells 120 and the portable electronic device 10 without any batteries interposing therebetween, which means the generated electric energy is directly transferred to the portable electronic device 10.

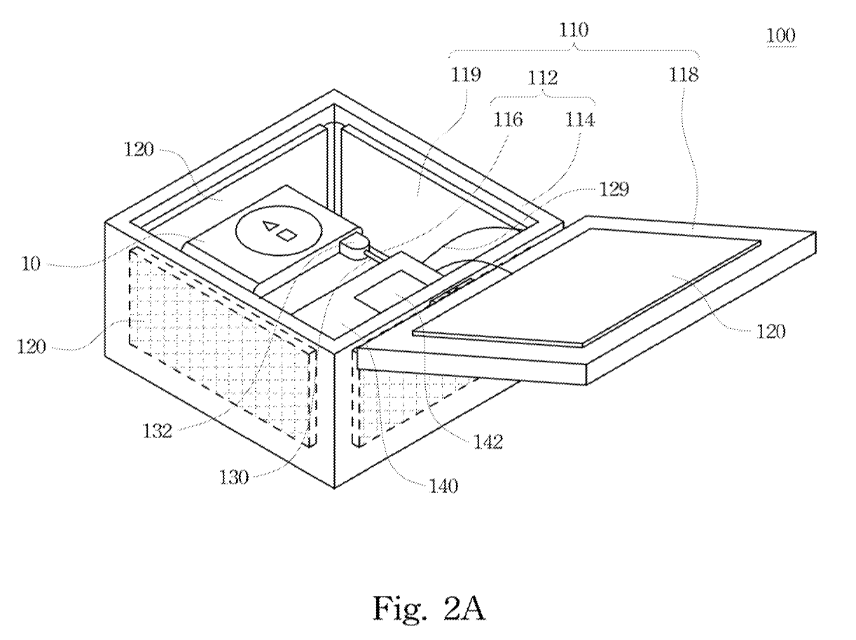

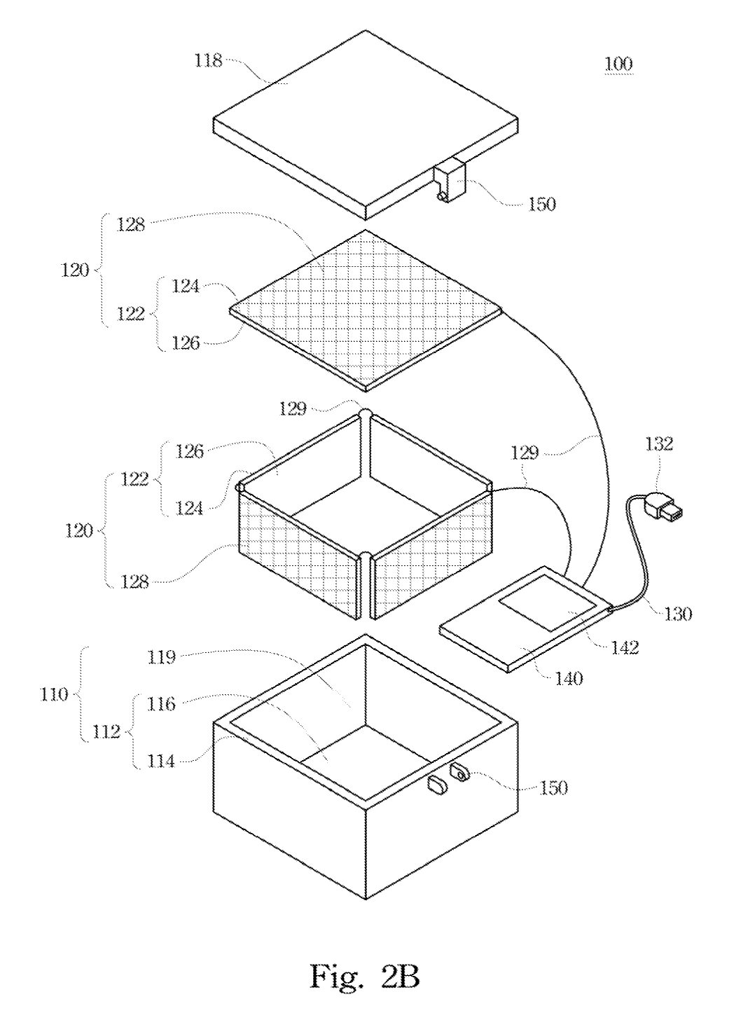

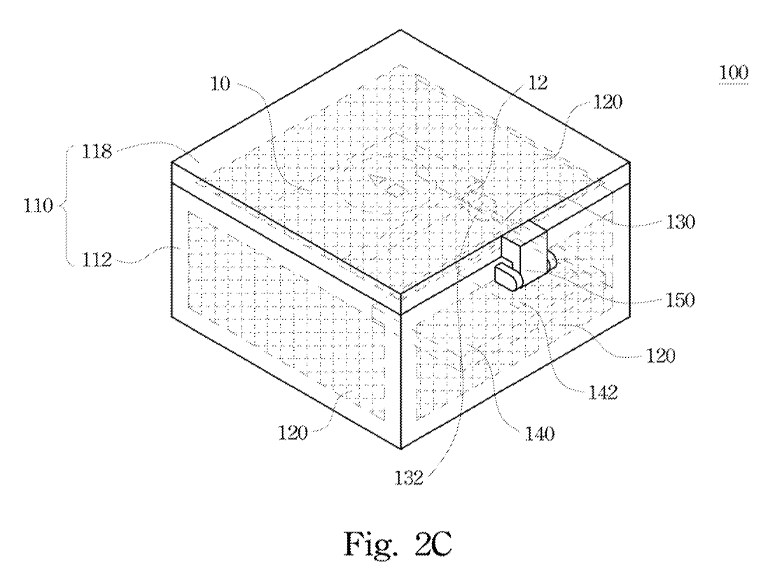

Please refer to FIG. 2A, FIG. 2B, and FIG. 2C at the same time. Both FIG. 2A and FIG. 2C are three-dimensional views of a packaging structure 100 according to another embodiment of this invention, wherein FIG. 2A shows a situation when the lid 118 is opened and FIG. 2C shows a situation when the lid 118 is closed. FIG. 2B is an exploded view of the packaging structure 100.

In the embodiment of this invention, the plates 112 and the lid 118 are transparent. The substrate 122 of the solar cells 120 are fastened on the side plates 114 and the lid 118, wherein the first surface 124 of the substrate 122 of each solar cell 120 is facing the inner surface of the side plate 114 or the lid 118. The active region 128 disposed on the first surface 124 may absorb light passing through the side plates 114 or the lid 118.

The lid 118 connects one of the side plates 114 via a joining element 150. In the embodiment of this invention, the joining element 150 is a latch. In particular, a bump is disposed on the lid 118 and the side plate 114 has a hole disposed thereon, wherein the bump may be jammed in the hole to form the latch.

The packaging structure 100 further comprises an inverter 142. The inverter 142 converts the electric voltage generated from the solar cells 120, wherein the inverter 142 may convert DC to AC, or convert AC to DC, or change the electric voltage. The inverter 142 may be a circuit, an integrated circuit, a chip, or combinations thereof. In the embodiment of this invention, the inverter 142 is disposed on a printed circuit board 140.

The inverter 142 electrically connects the solar cells 120 and the cable 130, wherein the cable 130 is directly connected to the inverter 142. The inverter 142 may connect each of the solar cells 120 via the wire 129 to receive the electric energy generated from the solar cells 120. An end of the cable 130 is directly connected to the inverter 142 and fastened on the printed circuit board 140, and the other end of the cable 130 has the connector 132 disposed thereon. Therefore, the electric energy converted by the inverter 142 may be directly transferred to the portable electronic device 10 via the cable 130 without other devices like batteries interposed therebetween.

The method for charging the portable electronic device 10 by using the packaging structure 100 of the embodiment is similar to the method described above.

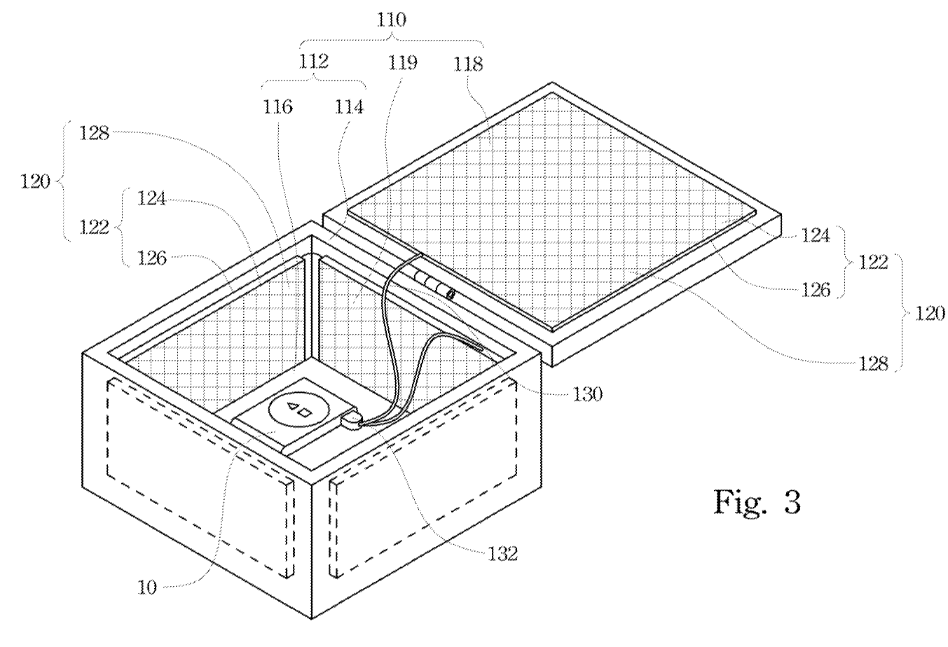

Please refer to FIG. 3. FIG. 3 is a three-dimensional view of a packaging structure 100 according to another embodiment of this invention. The plates 112 and the lid 118 of the box 110 of the embodiment of this invention may be transparent or opaque.

The solar cells 120 are fastened on the inner surfaces of the plates 112, wherein the second surface 126 of the substrate 122 thereof is facing the side plates 114. In other words, the first surface 124 and the active region 128 disposed thereon are facing the space inside the box 110.

In the embodiment of this invention, the solar cells are fastened on the plates 112 and the lid 118 as well. The solar cell is fastened on the inner surface of the lid 118, wherein the second surface 126 of the substrate 122 thereof faces the lid 118. When the lid 118 covers the box 110, the first surface 124 and the active region 128 of the solar cell 120 faces the space inside the box 110. Additionally, in another embodiment of this invention, the solar cells 120 may be fastened only on the plates 112, not on the lid 118.

When charging the portable electronic device 10 with the packaging structure 100 of the embodiment of this invention, the lid 118 should be removed to expose the opening 119. The cable 130 connected the solar cells 120 may connect the portable electronic device 10 via the connector 132. The box 110 should be placed in an environment with sufficient light. Since the lid 118 is removed to expose the space inside the box 110, the active region 128 on the first surface 124 of the substrate 122 may receive light from the environment.

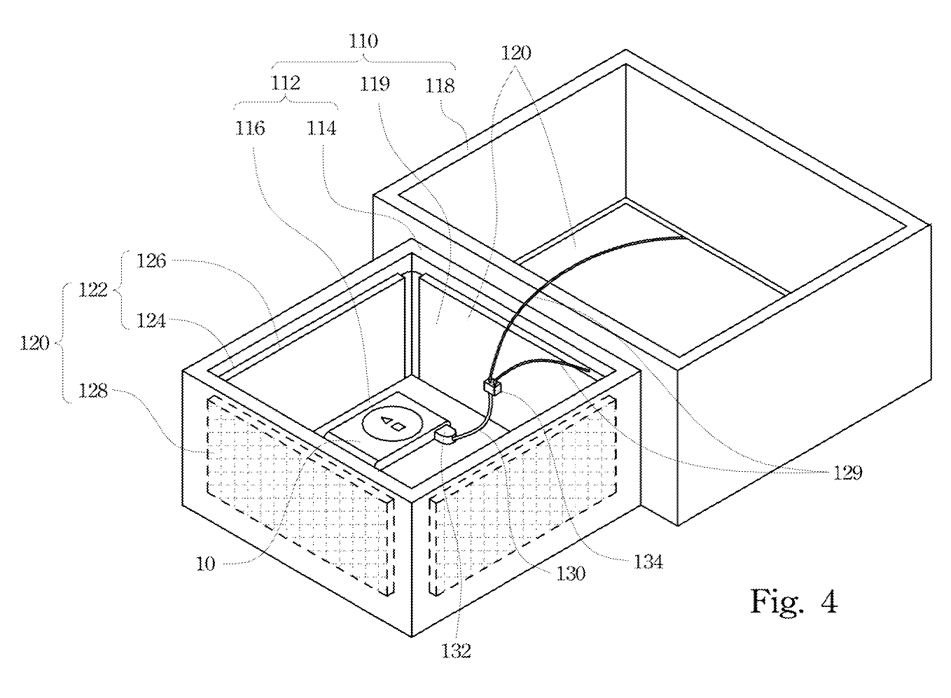

Please refer to FIG. 4. FIG. 4 is a three-dimensional view of a packaging structure 100 according to another embodiment of this invention. In the embodiment, the lid 118 is in a form like a pot to pivot on the plates 112. The lid 118 may pivot on the plates 112 to cover the opening 119, or may be removed to expose the opening 119. The lid 118 does not connect the plates 112, which means the lid 118 and the plates 112 are separated objects. In another embodiment of this invention, the lid 118 and the plates 112 are connected.

The length of the cable 130 may be increased to allow the lid 118 and the solar cells 120 disposed thereon to remove away from the plates 112. Additionally, the packaging structure 100 has an adapter 134. The adapter 134 may selectively connect or disconnect the cable 130 and the wire 129, which is connected to the solar cells 120. When the lid 118 is moved too far away from the plates 112, the adapter 134 may disconnect the wire 129 or the cable 130.

In the embodiment of this invention, the cable 130 has a connector 132 disposed on an end thereof, and the adapter 134 disposed on the other end thereof. The wire 129 connected to the solar cells 120 may plug in the adapter 134 to connect the cable 130. The wire 129 may be pull out of the adapter 134 to disconnect the cable 130.

In the embodiment of this invention, the plates 112 and the lid 118 may be transparent. The substrate 122 of each solar cell 120 is fastened on the lid 118 or the plates 112, wherein the first surface 124 of the substrate 122 is facing the lid 118 or the plate 112.

In another embodiment of this invention, the plates 112 and the lid 118 may be opaque. The second surface 126 of the substrate 122 of each solar cell 120 faces the lid 118 or the plate 112, which the substrate 122 is fastened on.

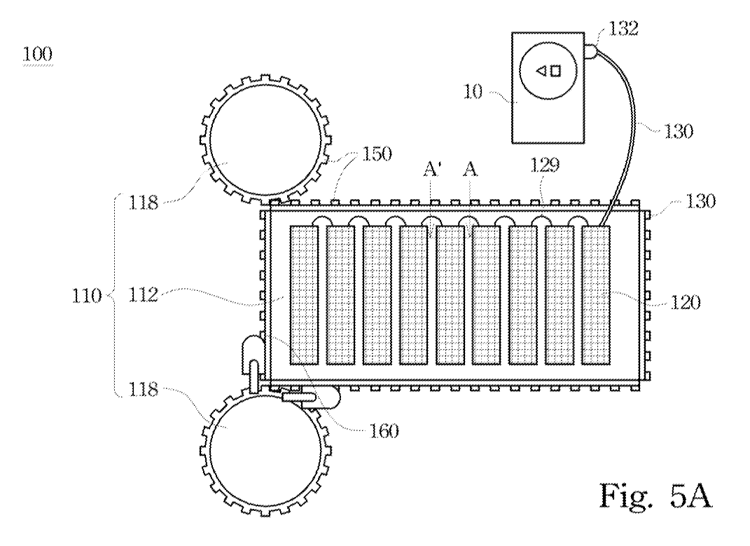

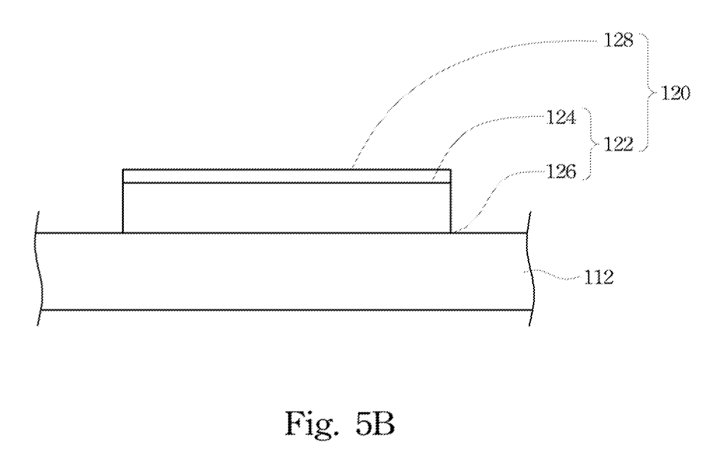

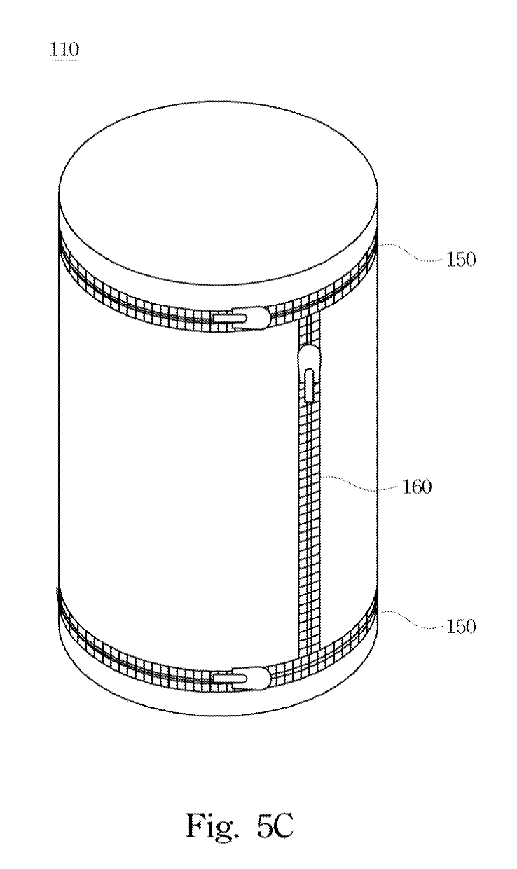

Please refer to FIG. 5A, FIG. 5B, and FIG. 5C at the same time. FIG. 5A is a top view of a packaging structure 100 according to another embodiment of this invention, wherein FIG. 5A shows the embodiment when the plate 112 is unfolded. FIG. 5B is a cross-section view of the packaging structure 100 according to the line A′ shown in FIG. 5A. FIG. 5C are three-dimensional views of the packaging structure 100, wherein FIG. 5C shows a situation when the plate 112 is folded to form a box 110.

In the embodiment of this invention, the plate 112 may be selectively folded to form a box 110 or unfolded to be spread over a plane surface. In other words, the plate 112 has two forms. In a first form, the plate 112 may be spread over a plane surface as shown in FIG. 5A. In a second form, the plate 112 may be folded to form a box 110 as shown in FIG. 5C, wherein the box 110 may contain the portable electronic device 10.

The shape of the box 110 formed by the folded plate 112 may be a cube, a cuboid, a cylinder, a cone, and etc. In the embodiment of this invention, the plate 112 is folded to form a cylinder. Two lids 118 are connected to two opposite sides of the plate 112 to cover two openings of the cylinder.

The packaging structure 100 has fastening elements 160 to maintain the shape of the folded plate 112. The fastening elements 160 may selectively connect or disconnect each to allow the plate 112 to be folded or unfolded. In other words, when the plate 112 is folded, the fastening elements 160 may be connected to maintain the shape of the box 110. When the fastening elements 160 are disconnected, the plate 112 may be spread. The fastening elements 160 may be buttons, bolts, zippers, or Velcro fastener. In the embodiment of this invention, the fastening elements 160 are zippers disposed separately on two opposite sides of the plate 112. When the plate 112 is folded like a cylinder, the zippers may be connected to each.

In the embodiment of this embodiment, the plate 112 may be made from a flexible material like paper, clothe, leather, and/or plastic materials. Additionally, the plate 112 may be made from transparent flexible materials like transparent plastic materials or Celluloid.

The solar cells 120 may be fastened on an inner surface of the plate 112, wherein the inner surface is the surface facing the inside of the box 110 when the plate 112 is folded. Therefore, the solar cells 120 are located in the box 110 when the plate 112 is folded.

In the embodiment of this invention, the second surface 126 of the substrate 122 of each solar cell 120 is facing the inner surface of the plate 112. The active region 128 is disposed on the first surface 124 of the substrate 122. When the plate 112 is spread in an environment with sufficient light, the first surface 124 and the active region 128 disposed thereon may receive light.

Although many solar cells 120 are fastened on the plate 112 in the embodiment, the number of solar cells 120 are not limited. The packaging structure 100 may have one solar cell 120. Additionally, the solar cell 120 may be flexible so that the solar cell 120 may be folded with the plate 112.

As the above, the sum of superficial areas of the solar cells 120 fastened on the box 110 is larger than a superficial area of the portable electronic device 10. In particular, the sum of superficial areas of the active regions 128 of the solar cells 120 is larger than a superficial area of the portable electronic device 10.

The cable 130 is electrically connected to the solar cells 120. In particular, the cable 130 may be directly connected to each of the solar cells 120. Additionally, the cable 130 may connect to one of the solar cells 120, wherein the solar cells 120 are connected to each via a wire 129.

The cable 130 has a connector 132 fastened on an end thereof for connecting the portable electronic device 10. In the embodiment of this invention, the connector 132 is a USB.

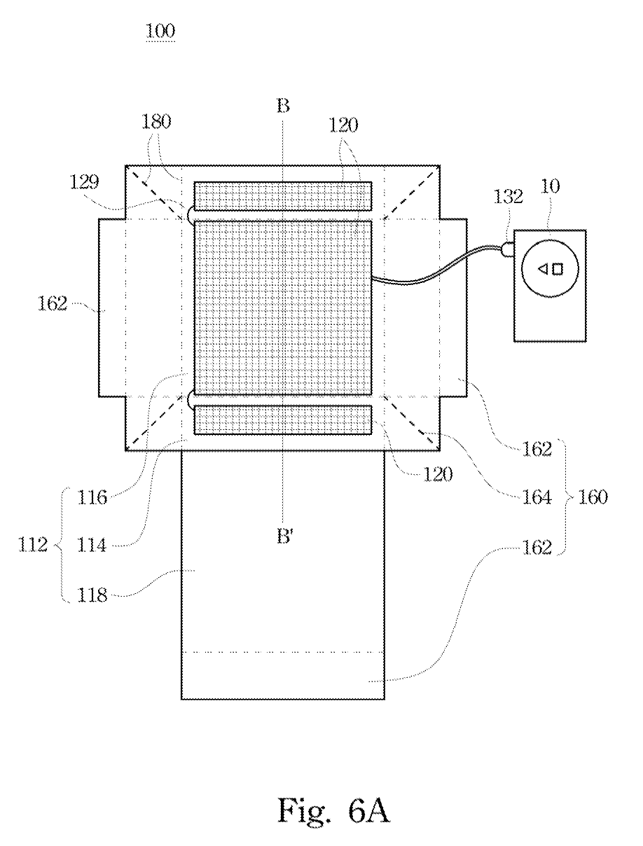

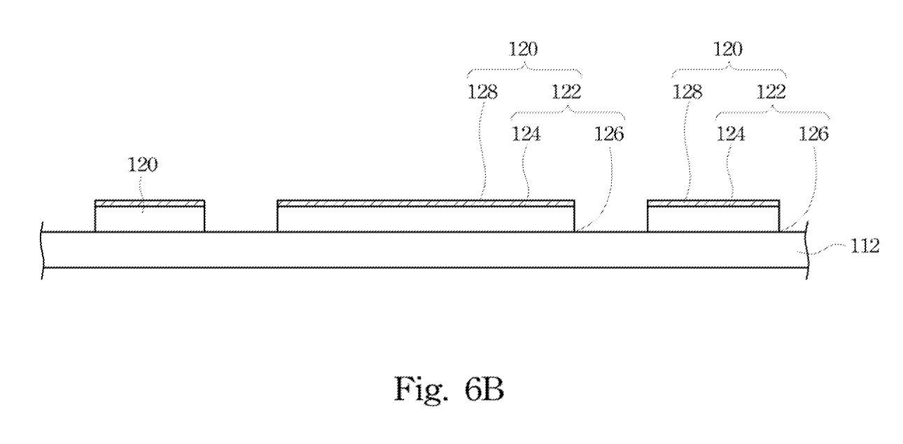

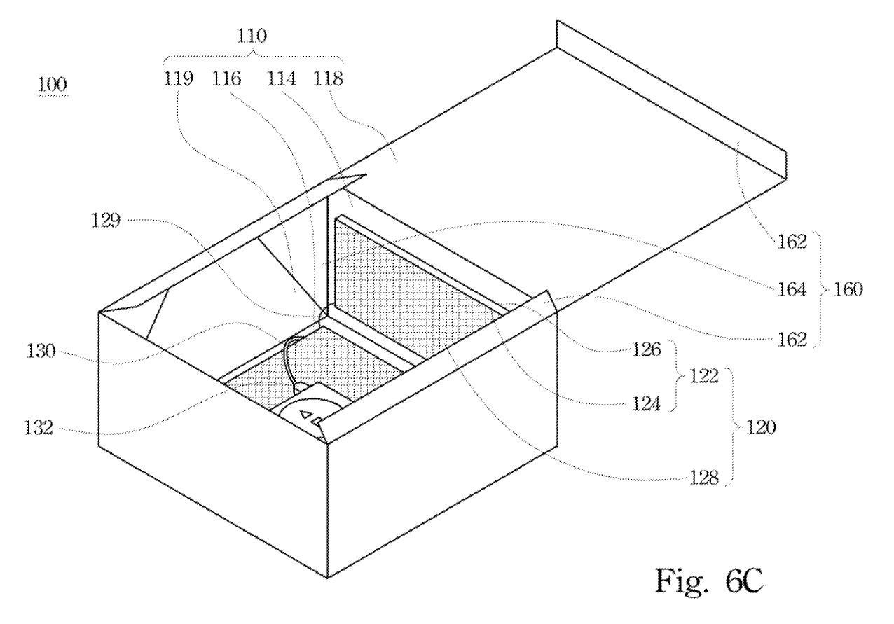

Please refer to FIG. 6A, FIG. 68, and FIG. 6C at the same time. FIG. 6A is a top view of a packaging structure 100 according to another embodiment of this invention, wherein FIG. 6A shows the embodiment when the plate 112 is unfolded. FIG. 6B is a cross-section view of the packaging structure 100 according to the line BB′ shown in FIG. 6A. FIG. 6C are three-dimensional views of the packaging structure 100, wherein FIG. 6C shows a situation when the plate 112 is folded to form a box 110.

In the embodiment of this invention, the plate 112 has side plates 114, a bottom plate 116, a lid 118, and bend lines 180 disposed between the side plates 114, the bottom plate 116, and the lid 118. The plate 112 may be folded along the bend lines 180 to form the box 110.

As the above, the plate 112 may be selectively folded to form a box 110 or unfolded to spread over a plane surface. Therefore, the plate 112 may be spread over a plane surface as shown in FIG. 6A, or the plate 112 may be folded to form a box 110 as shown in FIG. 6C.

In the embodiment of this invention, the packaging structure 100 has fastening elements 160, which may selectively connected or disconnected to each to allow the plate 112 being folded or unfolded. When the plate 112 is folded, the fastening elements 160 may be connected to maintain the shape of the box 110. When the fastening elements 160 are disconnected, the plate 112 may be spread. As the above, the kinds of the fastening elements 160 are many, such as buttons, bolts, zippers, or Velcro fastener.

In the embodiment of this invention, the fastening elements 160 comprise first folded portions 162 and second folded portions 164, wherein each second folded portion 164 is disposed between two side plates 114. When the second folded portion 164 is folded along the bend lines 180, the two side plates 114 connected the second folded portion 164 may contact each to form a corner of the box 110 as shown in FIG. 6C. When the second folded portion 180 is unfolded, the plate 112 may be spread.

The first folded portions 162 are connected to edges of the lid 118 and some of the side plates 114. The first folded portions 162 may be bent. In particular, a gap is between the bent first folded portions 162 connected to one of the side plate 114 and another side plate 114. The bent first folded portions 162 connected to the lid 118 may plug in the gap when the plate 112 is folded. When the bent first folded portions 162 connected to the lid 118 is pulled out of the gap, the plate 112 may be unfolded.

Therefore, the first folded portions 162 and the second folded portions 164 may selectively be connected or disconnected to each to allow the plate 112 being folded or unfolded.

The solar cells 120 may be fastened on the plate 112. When the plate 112 is folded, the solar cells 120 are located in the box 110. In the embodiment of this invention, the solar cells 120 are fastened on the side plates 114 and the bottom plate 116.

In the embodiment of this invention, the second surface 126 of the substrate 122 of each solar cell 120 is facing the inner surface of the plate 112. When the plate 112 is spread in an environment with sufficient light, the first surface 124 and the active region 128 disposed thereon may receive light.

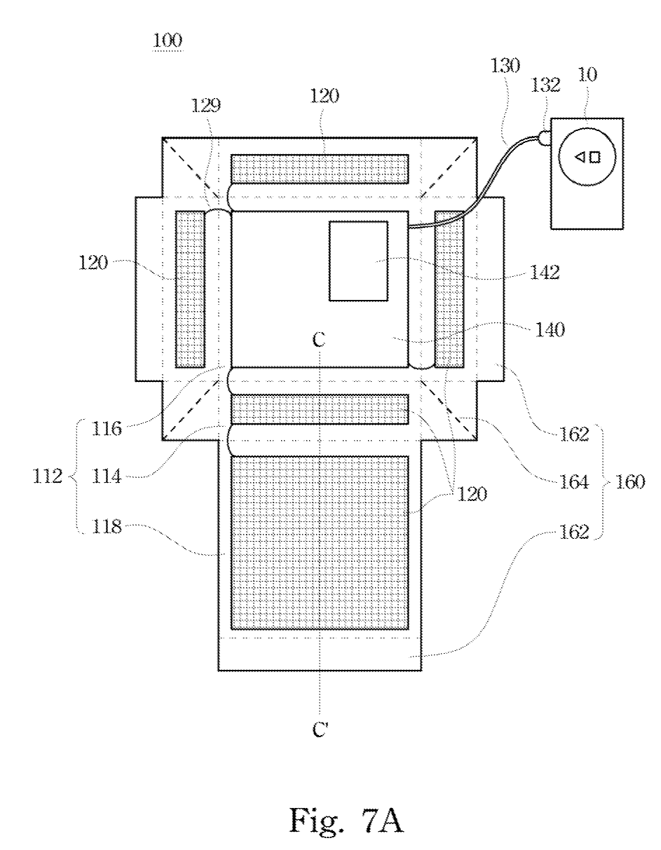

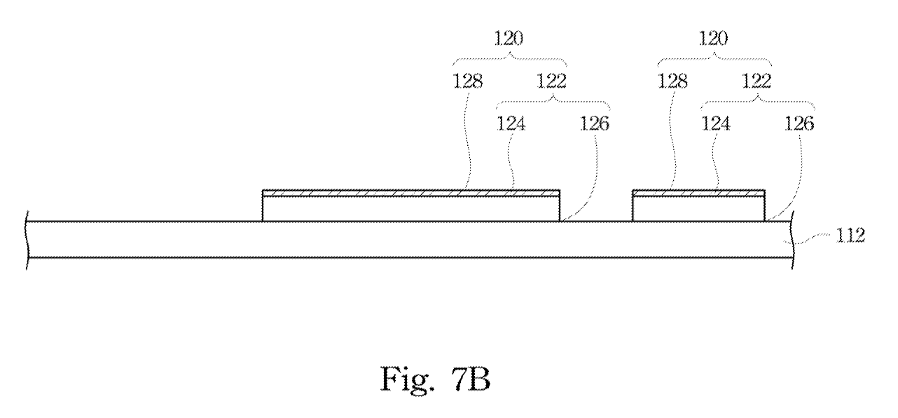

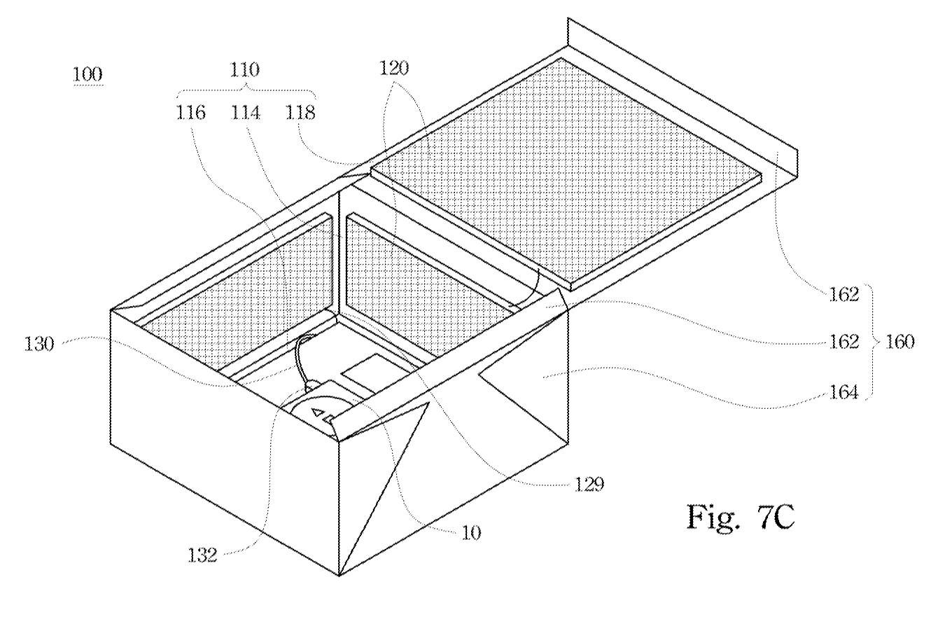

Please refer to FIG. 7A, FIG. 7B, and FIG. 7C at the same time. FIG. 7A is a top view of a packaging structure 100 according to another embodiment of this invention, wherein FIG. 7A shows the embodiment when the plate 112 is unfolded. FIG. 7B is a cross-section view of the packaging structure 100 according to the line CC′ shown in FIG. 7A. FIG. 7C are three-dimensional views of the packaging structure 100, wherein FIG. 7C shows a situation when the plate 112 is folded to form a box 110.

The plate 112 has side plates 114, a bottom plate 116, a lid 118, and bend lines 180 disposed between the side plates 114, the bottom plate 116, and the lid 118. The plate 112 may be folded along the bend lines 180 to form the box 110.

The solar cells 120 may be fastened on the plate 112. When the plate 112 is folded, the solar cells 120 are located in the box 110. In the embodiment of this invention, the solar cells 120 are fastened on the side plates 114 and the lid 118.

In the embodiment of this invention, the second surface 126 of the substrate 122 of each solar cell 120 is facing the inner surface of the plate 112. When the plate 112 is spread in an environment with sufficient light, the first surface 124 and the active region 128 disposed thereon may receive light.

In another embodiment of this invention, the plate 112 may be transparent. The first surface 124 of the substrate 122 of each solar cell 120 is facing the inner surface of the plate 112.

The packaging structure 100 further comprises a printed circuit board 140 and an inverter 142, wherein the inverter 142 is disposed on the printed circuit board 140.

The printed circuit board 140 and the inverter 142 disposed thereon are electrically connected to the solar cells 120. An end of the cable 130 is fastened on the printed circuit board 140 and electrically connected to the inverter 142, and the other end of the cable 130 connects the connector 132. Therefore, the electric energy, which has been converted by the inverter 142, may be directly transferred to the portable electronic device 10 via the cable 130.

In the foregoing, the packaging structure 100 may protect the portable electronic device 10 and may be operated for charging the portable electronic device 10 by solar energy.

Because the surface area of the box 110 should be larger than the surface area of the portable electronic device 10, the box 110 of the embodiments of this invention may be installed more solar cells 120.

Although the present invention has been described in considerable detail with reference certain embodiments thereof, other embodiments are possible. Therefore, their spirit and scope of the appended claims should no be limited to the description of the embodiments container herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A packaging structure, comprising:
a box comprising a plurality of plates connected to one another and surrounded to form an opening, and a lid selectively covering or exposing the opening, wherein at least a portable electronic device is placed in the box through the opening;
a plurality of first solar cells each fastened on an inner surface of each plate in the box; and
at least a cable electrically connected to the first solar cells and operated for electrically connecting the portable electronic device.

2. The packaging structure of claim 1, wherein the plates are transparent.

3. The packaging structure of claim 2, wherein the plates are made from polycarbonate, acrylic resin, or polystyrene.

4. The packaging structure of claim 2, wherein each first solar cell comprises a first substrate and a first active region disposed on a first surface of the first substrate, and the first surface facing one of the plates.

5. The packaging structure of claim 4, wherein a sum of superficial areas of the first active regions of the first solar cells is larger than a superficial area of the portable electronic device.

6. The packaging structure of claim 1, wherein each of the first solar cell comprises a first substrate and a first active region disposed on a first surface of the first substrate, the first and a second surfaces being a pair of opposite surfaces of the first substrate, and the second surface facing one of the plates.

7. The packaging structure of claim 6, wherein a sum of superficial areas of the first active regions of the first solar cells is larger than a superficial area of the portable electronic device.

8. The packaging structure of claim 1, further comprising a second solar cell fastened on an inner surface of the lid in the box and electrically connected to the cable.

9. The packaging structure of claim 8, wherein the lid is transparent.

10. The packaging structure of claim 9, wherein the second solar cell comprises a second substrate and a second active region disposed on a third surface of the second substrate, wherein the third surface of the second substrate is facing the lid.

11. The packaging structure of claim 9, wherein the lid is made from polycarbonate, acrylic resin, or polystyrene.

12. The packaging structure of claim 8, wherein the second solar cell comprises a second substrate and a second active region disposed on a third surface of the second substrate, the third and a fourth surfaces being a pair of opposite surfaces of the second substrate, and the fourth surface of the second substrate facing the lid.

13. The packaging structure of claim 1, further comprising a connector connected to an end of the cable for physically connecting the portable electronic device.

14. The packaging structure of claim 13, wherein the connector is a Universal Serial Bus (USB).

15. The packaging structure of claim 13, wherein the connector is directly connected to the first solar cells.

16. The packaging structure of claim 13, further comprising an inverter physically and electrically connected to the first solar cells for converting voltage generated from the first solar cells, wherein the cable is directly connected to the inverter.

17. A packaging structure, comprising:
at least a plate selectively folded to form a box or unfolded, wherein at least a portable electronic device is contained in the box when the plate is folded;
a plurality of solar cells fastened on the plate, wherein the solar cells are located in the box when the plate is folded; and
at least a cable physically and electrically connected to the solar cells and comprising a connector for connecting the portable electronic device.

18. The packaging structure of claim 17, wherein each solar cell comprises a substrate and an active region disposed on a first surface of the substrate, the first and a second surfaces being a pair of opposite surfaces of the substrate, and the second surface facing the plate.

19. The packaging structure of claim 17, wherein a sum of superficial areas of the active regions of the solar cells is larger than a superficial area of the portable electronic device.

20. The packaging structure of claim -17, further comprising a plurality of fastening elements disposed on the plate for selectively connected or disconnected to each, wherein the fastening elements are connected to each when the plate are folded.
